(19) United States
(12) Patent Application Publication
(10) Pub. No.: US 2011/0260231 A1
(43) Pub. Date: Oct. 27, 2011

(54) MEMORY DEVICE AND METHOD FOR MANUFACTURING THE SAME

(75) Inventors: Qingqing Liang, Beijing (CN); Huicai Zhong, Beijing (CN)

(73) Assignee: Institute of Microelectronics, Chinese Academy of Sciences, Beijing (CN)

(21) Appl. No.: 13/003,723

(22) PCT Filed: Sep. 21, 2010
(86) PCT No.: PCT/CN2010/001460

§ 371 Date: Jan. 11, 2011

(30) Foreign Application Priority Data
Apr. 21, 2010 (CN) 201010157573.7

(51) Int. Cl. H01L 27/108; H01L 21/84; H01L 21/8242

(52) U.S. Cl. 257/307; 438/253; 438/155; 257/E27.084; 257/E21.7; 257/E21.646

(57) ABSTRACT

The present application discloses a memory device and a method for manufacturing the same. The memory device comprising an MOSFET formed in a semiconductor layer and a capacitor structure below the MOSFET, wherein the capacitor structure comprises two capacitor electrodes, and one of a source region and a drain region of the MOSFET is electrically connected to one of the two capacitor electrodes, wherein the capacitor structure comprises a plurality of first sub-capacitors and a plurality of second sub-capacitors which are stacked in an alternate manner, each of the plurality of the first sub-capacitors and the plurality of the second sub-capacitors comprises a top capacitor plate, a bottom capacitor plate and a dielectric layer sandwiched therebetween, and the plurality of the first sub-capacitors and the plurality of the second sub-capacitors are connected in parallel with the two capacitor electrodes, and wherein each of the first sub-capacitors has a bottom capacitor plate which is formed from a common first electrode layer with a top capacitor plate of an underlying second sub-capacitor, and each of the second sub-capacitors has a bottom capacitor plate which is formed from a common second electrode layer with a top capacitor plate of an underlying first sub-capacitor, and wherein the first electrode layer and the second electrode layer are made of different conductive materials.

### BACKGROUND OF THE INVENTION

1. Field of Invention

The present invention relates to a memory device and a method for manufacturing the same, and more particularly, to an embedded memory device having an integrated capacitor and a method for manufacturing the same.

2. Description of Prior Art

An embedded memory device having an integrated capacitor, such as an eDRAM, is widely used in an electronic device such as a cellular phone due to its small size and low power consumption. In the eDRAM, a capacitance value of memory cell is of critical importance to a retention time. A larger capacitance value of memory cell leads to a longer retention time, which means that a capacitor having a large size is usually integrated in a chip. However, the capacitor having a large size decreases an integration density of the memory cell.

Wang Geng et al. proposed an eDRAM cell having a deep trench capacitor formed in a substrate in U.S. patent application US20090174031A1. Sidewalls of the trench provide most portions of capacitor plates, which reduce a footprint of the eDRAM cell, while still providing a large capacitance value.

However, the eDRAM cell comprising a deep trench capacitor causes new difficulties in manufacturing process. For example, since the deep trench has a large aspect ratio, a reactive ion etching (RIE) process will take a long time for providing the deep trench, and voids are possibly introduced in a subsequent metal filling process. Consequently, the eDRAM cell having the deep trench capacitor incurs a high manufacturing cost and a poor reliability.

Also, the above difficulties in the manufacturing processes limit the depth of the trench. The resultant capacitance value is possibly too small to provide the desired retention time of the eDRAM cell.

### SUMMARY OF THE INVENTION

An object of the present invention is to provide a memory device having a large integration density, a high reliability and a long retention time, and a method for manufacturing the same.

According to one aspect of the invention, there provides a memory device comprising an MOSFET formed in a semiconductor layer and a capacitor structure below the MOSFET, wherein the capacitor structure comprises two capacitor electrodes, and one of a source region and a drain region of the MOSFET is electrically connected to one of the two capacitor electrodes, wherein the capacitor structure comprises a plurality of first sub-capacitors and a plurality of second sub-capacitors which are stacked in an alternate manner, each of the plurality of the first sub-capacitors and the plurality of the second sub-capacitors comprises a top capacitor plate, a bottom capacitor plate and a dielectric layer sandwiched therebetween, and the plurality of the first sub-capacitors and the plurality of the second sub-capacitors are connected in parallel with the two capacitor electrodes, and wherein each of the first sub-capacitors has a bottom capacitor plate which is formed from a common first electrode layer with a top capacitor plate of an underlying second sub-capacitor, and each of the second sub-capacitors has a bottom capacitor plate which is formed from a common second electrode layer with a top capacitor plate of an underlying first sub-capacitor, and wherein the first electrode layer and the second electrode layer are made of different conductive materials.

According to another aspect of the invention, there provides a method for manufacturing a memory device, comprising steps of: a) forming repeated stacks of a first dielectric layer, a first electrode layer, a second dielectric layer, and a second electrode layer in an alternate manner on a semiconductor substrate, so as to form a multi-layer structure, the semiconductor substrate having a bottom substrate, a sacrificial layer, and a top semiconductor layer; b) etching a first side of the multi-layer structure, in which the exposed portion of the second electrode layer at the first side is selectively removed with respect to the first electrode layer, the first dielectric layer, and the second dielectric layer, so that recesses remain at the first side; c) etching a second side of the multi-layer structure, in which the exposed portion of the first electrode layer at the second side is selectively removed with respect to the first dielectric layer, the second electrode layer, and the second dielectric layer, so that recesses remain at the second side; d) forming a capping layer of insulating material on the multi-layer structure; e) forming capacitor openings in the capping layer, which expose the first side and the second side of the multi-layer structure, and in which the insulating material remains in the recesses at the first side and the second side; and f) forming two capacitor electrodes by filling the capacitor openings with a conductive material, the two capacitor electrodes contact directly all of the first electrode layer and all of the second electrode layer, respectively; g) turning the semiconductor substrate upside down and removing the bottom substrate and the sacrificial layer; h) forming a source region, a drain region, and a channel region therebetween of the MOSFET in the top semiconductor layer, wherein one of the source region and the drain region of the MOSFET is electrically connected to one of the two capacitor electrodes; and i) forming a gate dielectric and a gate conductor above the channel region of the MOSFET.

In the present memory device, the capacitor structure has a relatively small footprint on the chip and a relatively large capacitance value because a plurality of sub-capacitors are stacked and connected in parallel with each other. The memory device thus has a large integration density and a long retention time.

Moreover, since the first electrode layer and the second electrode layer are made of different materials, the capacitor structure can be easily formed in several etching steps by using masks, which is compatible with the conventional integrated circuit process.

Furthermore, the capacitance value of capacitor structure can be easily tuned by changing the number of sub-capacitors. This introduces an additional degree of freedom in the design of memory device. There is no need to etch a deep trench having a large aspect ratio and then fill it with a metal in the manufacture process. The resultant memory device has no defects introduced by the filling step, which improves a reliability of the device.

### BRIEF DESCRIPTION OF THE DRAWINGS

FIGS. 1-14 schematically show cross sectional views of the semiconductor structure of memory device at various stages of forming a capacitor structure according to the present invention.

FIGS. 15-16 schematically show cross sectional views of the semiconductor structure of memory device at various stages of forming an MOSFET (metal-oxide-semiconductor field effect transistor) process according to the present invention.

### DETAILED DESCRIPTION OF PREFERRED EMBODIMENTS

Exemplary embodiments of the present invention are described in detail below with reference to the accompanying drawings. In the attached drawings, like reference numerals denote like members. The figures are not drawn to scale, for the sake of clarity.

It should be understood that when one layer or region is referred to as being “above” or “on” another layer or region in the description of device structure, it can be directly above or on the other layer or region, or other layers or regions may be intervened therebetween. Moreover, if the device in the figures is turned over, the layer or region will be “under” or “below” the other layer or region.

In contrast, when one layer is referred to as being “directly on” or “on and adjacent to” another layer or region, there are not intervening layers or regions present.

Some particular details of the invention will be described, such as an exemplary structure, material, dimension, process step and fabricating method of the device, for a better understanding of the present invention. Nevertheless, it is understood by one skilled person in the art that these details are not always essential for but can be varied in a specific implementation of the invention

According to a preferred embodiment of the inventive method, the steps shown in FIGS. 1-14 are performed in this order for forming a capacitor structure.

As shown in FIG. 1, the inventive method starts with an SOI (semiconductor on insulator) wafer. The SOI wafer comprises a bottom substrate 11, a buried insulating layer (BOX) 12 and a top semiconductor layer 13. The top semiconductor layer 13 can be made of for example a group IV semiconductor (such as silicon, germanium) or group III-V semiconductor (such as gallium arsenide).

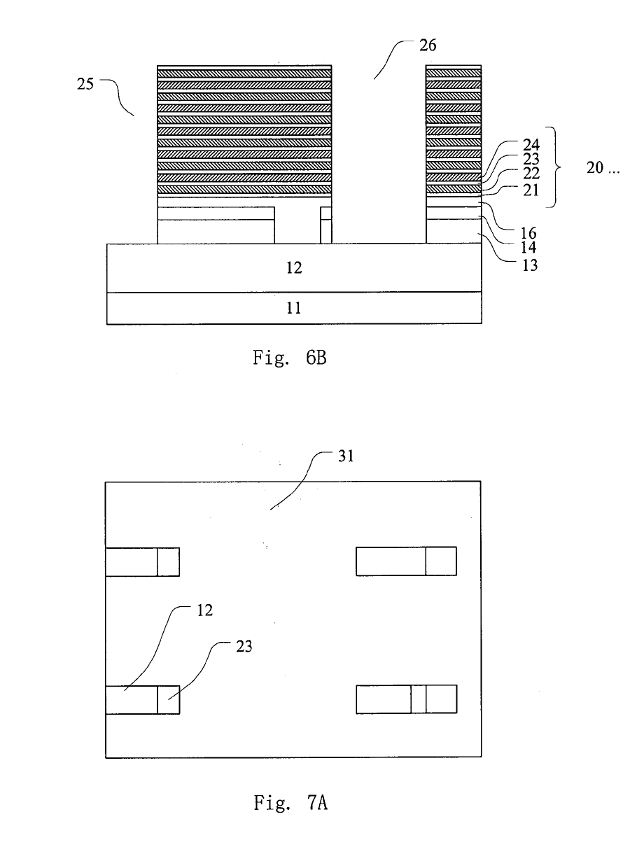

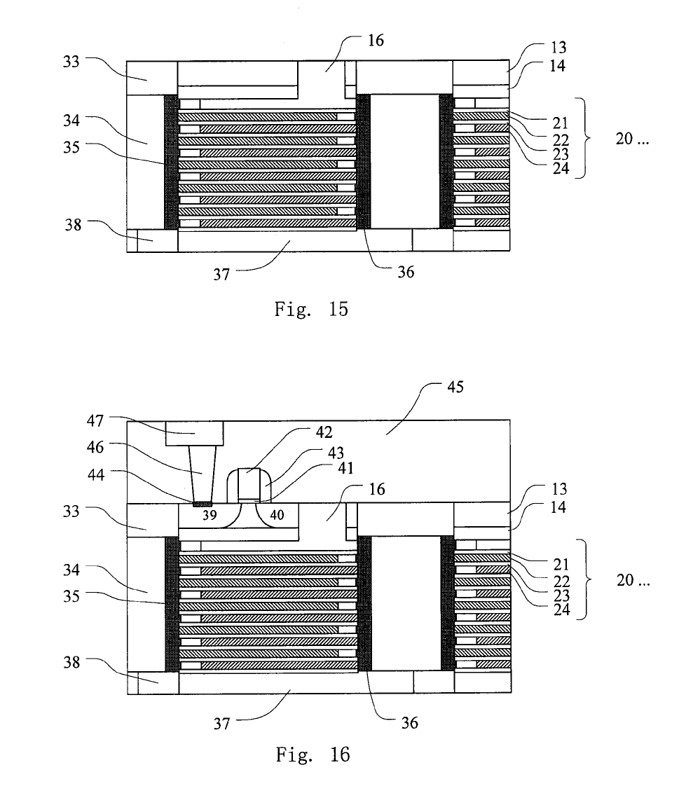

Alternatively, a bulk silicon substrate can be used for replacing the above bottom substrate 11. An epitaxial SiGe layer is then formed on the bulk silicon substrate for replacing the above buried insulating layer 12. An epitaxial semiconductor layer is then formed on the SiGe layer for replacing the top semiconductor layer 13. In the present invention, the buried insulating layer 12, or the SiGe layer as an alternative, is used as a stop layer in the etching step shown in FIGS. 6A and 6B and also acts as a sacrificial layer in FIG. 15.

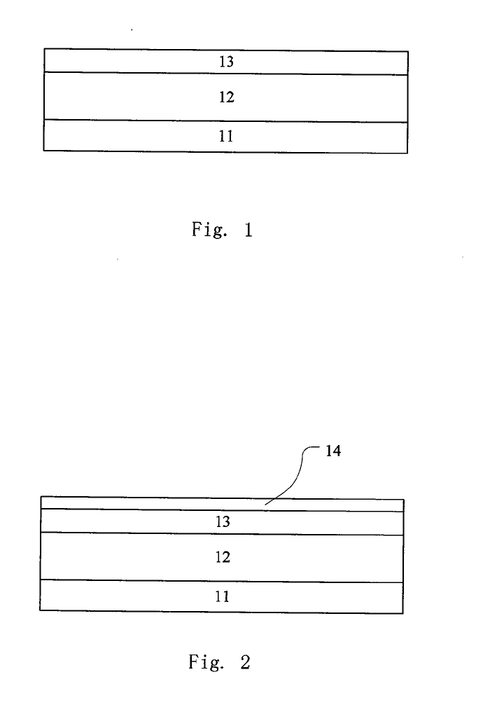

As shown in FIG. 2, an oxide layer 14 is formed on the top semiconductor layer 13 of the SOI wafer, by a conventional deposition process, such as PVD, CVD, atomic layer deposition, sputtering and the like.

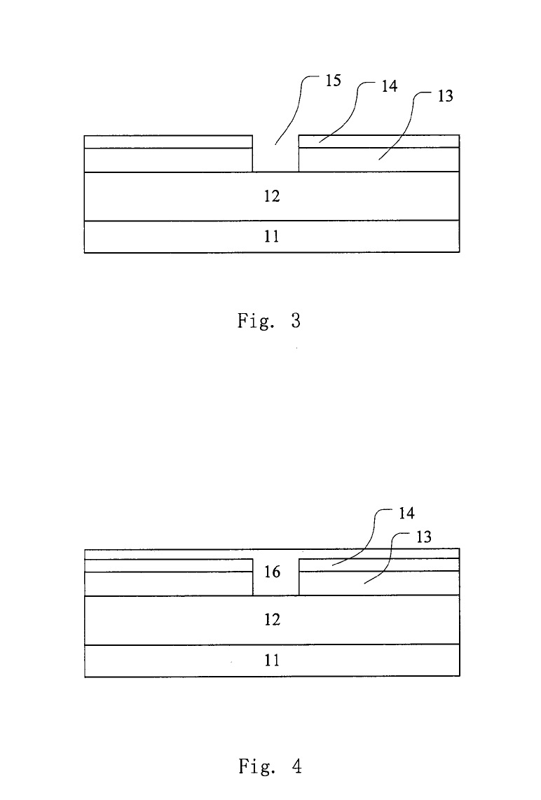

As shown in FIG. 3, an opening 15 is formed through patterning in the above oxide layer 14 and the top semiconductor layer (referred as “SOI semiconductor layer” hereinafter) 13 of the SOI wafer, by an etching process using a photoresist mask, and is then used as a via hole for the capacitor and the MOS transistor in the resultant memory device.

The following steps may be involved in the patterning process: a photoresist mask having a pattern therein is formed on the oxide layer 14, by a conventional photolithographical process including exposure and development steps; the exposed portions of the SOI semiconductor layer 13 and the oxide layer 14 are removed by dry etching such as ion beam milling, plasma etching, reactive ion etching, laser ablation and the like, or wet etching using a solution of etchant, stopping at the top of the buried oxide layer 12; and the photoresist mask is then removed by ashing or dissolution with a solvent.

As shown in FIG. 4, a (doped) conductive polysilicon layer 16 is deposited on the semiconductor structure of memory device which is obtained after the above steps, and then is subjected to a chemical mechanical planarization (CMP) so as to provide a flat surface for the semiconductor structure of memory device. The polysilicon layer 16 fills up the opening 15, and contacts the SOI semiconductor layer 13 at a lower portion of the side wall of the opening 15. After CMP, the polysilicon layer 16 has a thickness of about 5-20 nm on the top of the oxide layer 14.

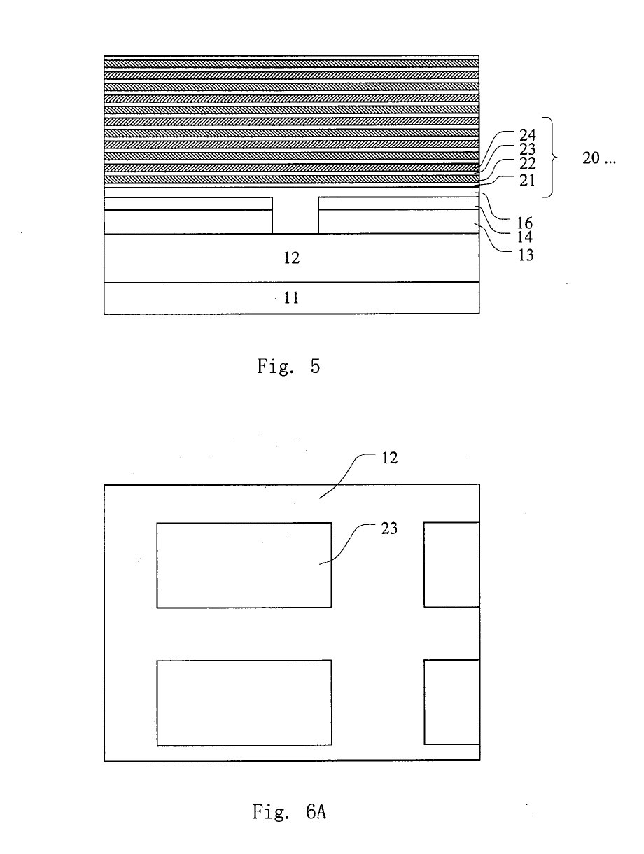

As shown in FIG. 5, a first dielectric layer 21, a first electrode layer 22, a second dielectric layer 23, and a second electrode layer 24 are then deposited alternately on the polysilicon layer 16, by a conventional deposition process, such as PVD, CVD, atomic layer deposition, sputtering and the like, so as to form a multi-layer structure comprising repeated stacks 20 of the first dielectric layer 21, the first electrode layer 22, the second dielectric layer 23 and the second electrode layer 24.

In a prior design of the memory device, the available footprint for each memory cell limits a planar area of the capacitor. As will be discussed below, the inventive capacitor structure comprises the repeated stacks 20 that provide a plurality of sub-capacitors connected in parallel and thus gives the desired capacitance value with a reduced footprint.

The minimum of the footprint of the first electrode 22 and the second electrode 24 depends only on the process level.

To provide the desired capacitance value, various parameters such as areas of the first electrode layer 22 and the second electrode layer 24, materials and thicknesses of the first dielectric layer 21 and the second dielectric layer 23, and the number of the stacks 20 can be tuned. As an example, the stacks 20 of the first electrode layer 21, the first dielectric layer 22, the second electrode layer 23 and the second dielectric layer 24 repeat 10-1000 times, and each have a thickness of about 20-40 nm.

The first electrode layer 22 and the second electrode layer 24 are both used as capacitor plates, and can be a metal layer, a doped polysilicon layer, or a stack of a metal layer and a doped polysilicon layer. The metal layer is made of one selected from a group consisting of TaC, TiN, TaTbN, TaErN, TaYbN, TaSiN, HfSiN, MoSiN, RuTax, NiTax, MoNx, TiSiN, TiCN, TaAlC, TiAlN, TaN, PtSix, Ni3Si, Pt, Ru, Ir, Mo, HfRu, and RuOx, or their combinations.

As will be mentioned above, the first electrode layer 22 and the second electrode layer 24 are made of the materials having different etching rate in an etching step. Preferably, the first electrode layer 22 is made of TiN, and the second electrode layer 24 is made of polysilicon.

The first dielectric layer 21 and the second dielectric layer 23 can be made of the same or the different dielectric materials, such as oxides, nitrides, oxynitrides, silicates, aluminates, titanates, and the like. The oxides include for example SiO2, HfO2, ZrO2, Al2O3, TiO2, and La2O3. The nitrides include for example Si3N4. The silicates include for example HfSiOx. The aluminates include for example LaAlO3. The titanates include for example SrTiO3. The oxynitrides include for example SiON. Moreover, the dielectric materials can be those developed in the future, besides the above known materials.

As shown in FIGS. 6A and 6B, the multi-layer structure, the polysilicon layer 16, the oxide layer 14 and the SOI semiconductor layer 13 are patterned together by a conventional etching process using a photoresist mask to provide a rectangular region for each memory cell. FIGS. 6A and 6B show a top view and a cross sectional view of the semiconductor structure of memory device at this stage, respectively. The etching exposes the side walls of the multi-layer structure, and stops at the top of the buried insulating layer 12.

Alternatively, if a bulk silicon substrate is used in the step shown in FIG. 1, the etching stops at the top of the epitaxial SiGe layer. Then, the photoresist mask is removed by ashing or dissolution with a solvent.

It should be noted that two memory devices are separated by the opening 26 in FIGS. 6A and 6B. In fact, a plurality of memory devices can be formed on a substrate in similar arrangements. For simplicity, only the one memory device at the left side of the opening 26 and its manufacturing steps are illustrated in the following paragraphs.

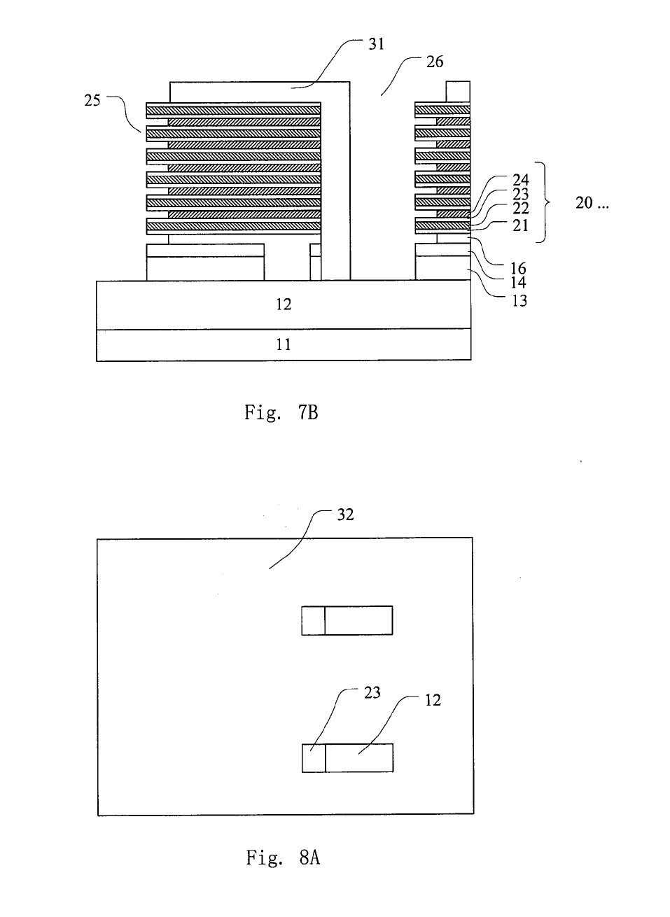

As shown in FIGS. 7A and 7B, a photoresist mask 31 is formed by the conventional lithographical process. FIGS. 7A and 7B show a top view and a cross sectional view of the semiconductor structure of memory device at this stage, respectively. The photoresist mask 31 exposes one side (i.e. the side located in the opening 25, referred as “the first side” hereinafter) of the multi-layer structure, and covers the other side (i.e. the side located in the opening 26, referred as “the second side” hereinafter) and most of the top surface of the multi-layer structure.

Then, exposed portions of the second electrode layer 24 are selective removed with respect to the first dielectric layer 21, the first electrode layer 22, and the second dielectric layer 23 by an isotropic etching process, such as conventional wet etching using a solution of etchant.

Due to the presence of the photoresist mask 31, only the portions of the second electrode layer 24 at the first side are etched away, and reaches laterally a depth (i.e. from a side wall to an inside of the multi-layer structure) of about 2-10 nm so as to form recesses at the first side of the multi-layer structure.

Further, in a case that the second electrode layer 24 is made of the same material to as that of the polysilicon layer 16, a portion of the polysilicon layer 16 is also removed.

Then, the photoresist mask is removed by ashing or dissolution with a solvent.

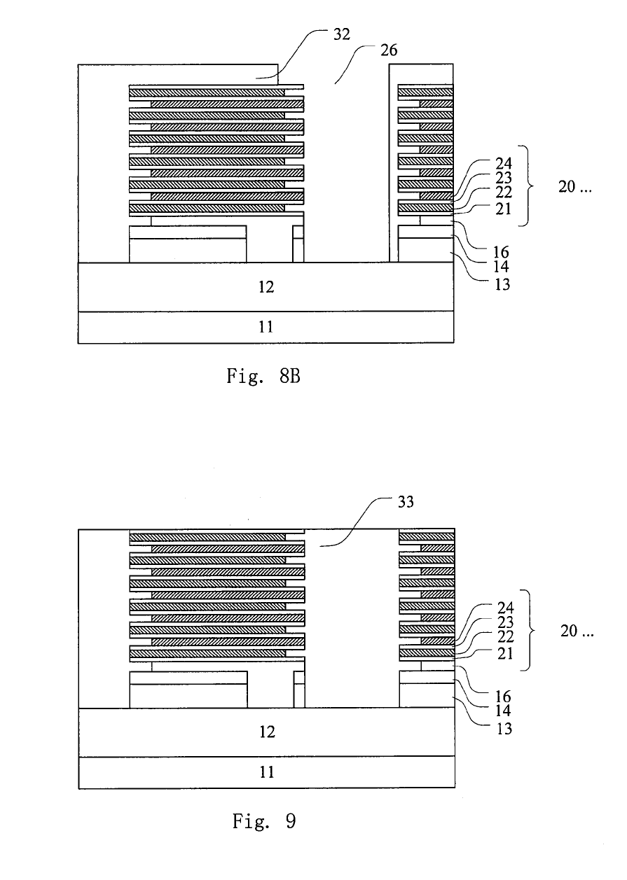

As shown in FIGS. 8A and 8B, a photoresist mask 32 is formed by the conventional lithographical process. FIGS. 8A and 8B show a top view and a cross sectional view of the semiconductor structure of memory device at this stage, respectively. The photoresist mask 32 exposes the second side of the multi-layer structure, but covers the first side and most of the top surface of the multi-layer structure.

Then, exposed portions of the first electrode layer 22 are selectively removed with respect to the first dielectric layer 21, the second dielectric layer 23, and the second electrode layer 24, by an isotropic etching process, such as conventional wet etching using a solution of etchant.

Due to the presence of the photoresist mask 32, only the portions of the first electrode layer 22 at the second side are etched away, and reaches laterally a depth (i.e. from a side wall to an inside of the multi-layer structure) of about 2-10 nm so as to form recesses at the second side of the multi-layer structure.

Then, the photoresist mask is removed by ashing or dissolution with a solvent.

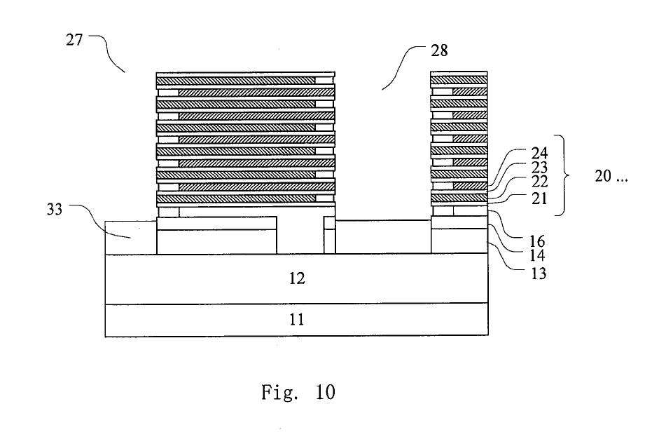

As shown in FIG. 9, an insulating layer 33 such as SiO2 is deposited on the multi-layer structure, by a conventional deposition process, such as PVD, CVD, atomic layer deposition, sputtering and the like. The insulating layer 33 has a thickness sufficient for covering the whole multi-layer structure, and then is subjected to a CMP process so as to provide a flat surface for the multi-layer structure. The CMP stops on the top-most second dielectric layer 23 of the multi-layer structure, and also removes the second electrode layer 24 on the top-most second dielectric layer 23.

It should be noted that the insulating layer 33 fills the recesses at the first side and the second side of the multi-layer structure.

As shown in FIG. 10, a portion of the insulating layer 33 is etched away so as to form new openings 27 and 28 at the positions of the previous openings 25 and 26.

The etching process for the openings 27 and 28 is typically anisotropic, such as an reactive ion etching (RIE) process. As mentioned above, the insulating layer 33 fills the recesses at the first side and the second side of the multi-layer structure. Thus, at the step of forming the openings 27 and 28, the portions of the insulating material in the recesses remain. The portions of the Insulating layer in the recesses at the first side of the multi-layer structure electrically isolate the second electrode layer 24 from the first electrode to be formed, and the portions of the Insulating layer in the recesses at the second side of the multi-layer structure electrically isolate the first electrode layer 22 from the second electrode to be formed.

Also, a portion of the insulating material of the insulating layer 33 remains at the bottom of the openings 27 and 28. By controlling an etching depth, the top surface of the remaining insulating layer 33 is located at a position between the top surface and the bottom surface of the oxide layer 14. Thus, the remaining portion of the insulating layer 33 electrically isolates the first and the second electrodes to be formed from the SOI semiconductor layer 13 located below the oxide layer 14, while the second electrode electrically contacts the polysilicon layer 16 located above the oxide layer 14.

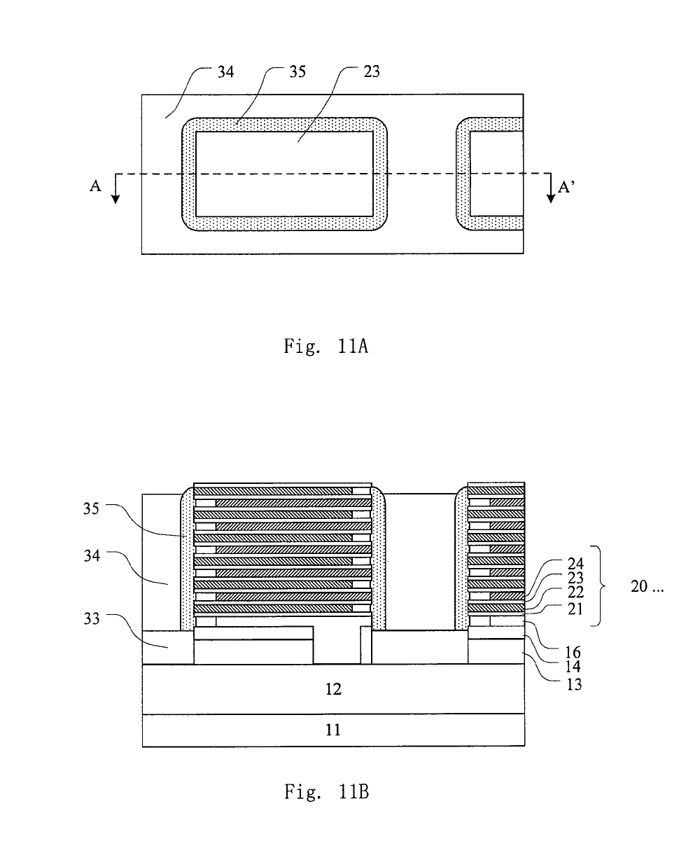

As shown in FIGS. 11A and 11B, a sidewall spacer 35 is formed around the rectangular region of each memory cell. FIGS. 11A and 11B show a top view and a cross sectional view of the semiconductor structure of memory device at this stage, respectively.

The sidewall spacer 35 can be formed by those steps for forming the sidewall spacer surrounding the gate of a transistor, as well known in the art. For example, thin SiN layer, which has good sidewall coverage on the rectangular region, may be firstly deposited by LPCVD, ALD, PECVD and the like. The thin SiN layer is then etched laterally so that one portion of the thin SiN layer located at the top and the periphery of the rectangular region is removed, while the other portion of the thin SiN layer located at the sides of the rectangular region remains.

An oxide layer 34 is then deposited, followed by CMP, so that the oxide layer 34 fills the recesses at the periphery of the sidewall spacers 35.

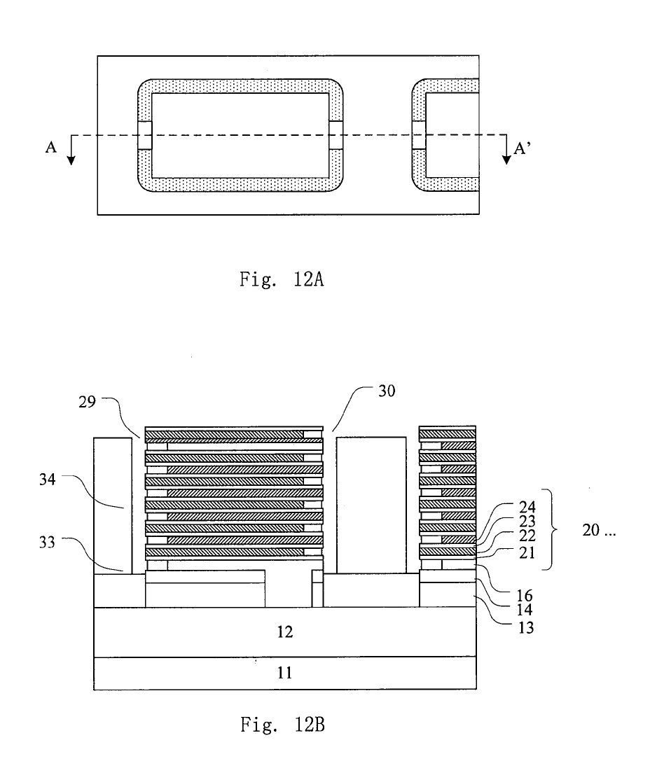

As shown in FIGS. 12A and 12B, the sidewall spacer 35 of SiN is etched by a conventional patterning process using a photoresist mask so as to form capacitor openings 29, 30. FIGS. 12A and 12B show a top view and a cross sectional view of the semiconductor structure of memory device at this stage respectively. The capacitor openings 29, 30 are arranged at the positions located in the previous openings of the photoresist mask 31, 32, and expose the first and second sides of the multi-layer structure for the first and second electrodes to be formed. The steps for forming the openings 29, 30 are similar to those for forming the openings 27, 28 shown in FIG. 10, in which an anisotropic etching process is used, such as an reactive ion etching (RIE) process.

As shown in FIG. 13, conductive material such as tungsten is deposited in the capacitor openings 29, 30, by a conventional deposition process, such as PVD, CVD, atomic layer deposition, sputtering and the like.

The conductive material in the capacitor opening 29 contacts all of the first electrode layers 22 of the multi-layer structure, and forms a first capacitor electrode 35. The conductive material in the capacitor opening 30 contacts all of the second electrode layers 24 of the multi-layer structure, and forms a second capacitor electrode 36.

Moreover, a lower portion of the second capacitor electrode 36 contacts the polysilicon layer 16 formed in the step shown in FIG. 4, and provides a conductive path from the second capacitor electrode 36 to an MOSFET to be formed.

After the deposition of the conductive material, CMP is performed with the top-most dielectric layer of the multi-layer as a stop layer, so as to provide a flat surface for the semiconductor structure of memory device.

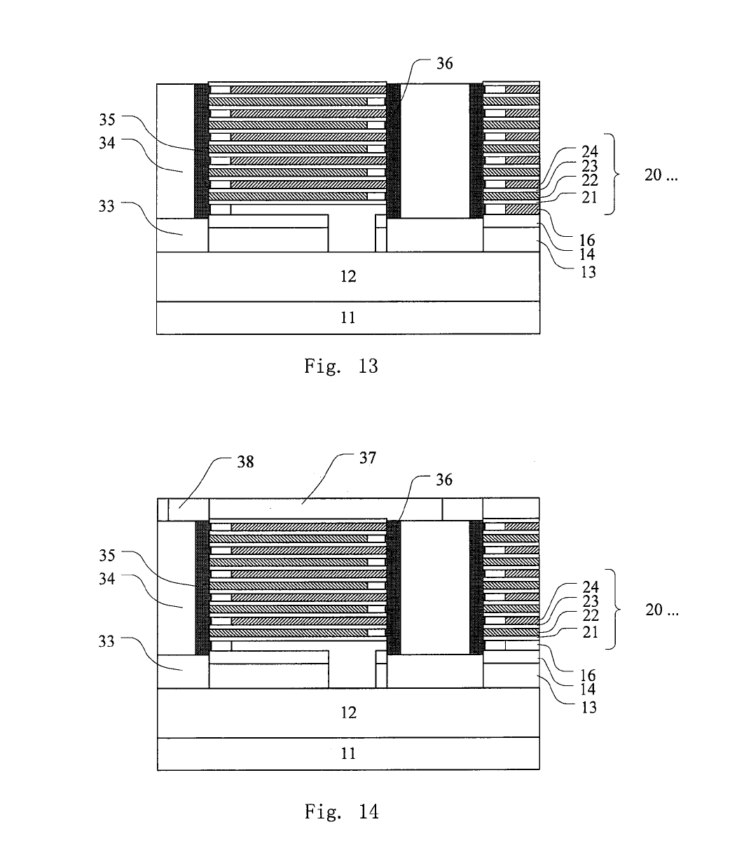

As shown in FIG. 14, an interlayer dielectric layer 37 is formed on the multi-layer structure, and a first contact hole 38 of the capacitor electrode is formed in the interlayer dielectric layer 37, for example at Back-End-Of-Line (BEOL). The first contact hole 38 of the capacitor electrode electrically contacts the first capacitor electrode 35 and is further connected to wirings (no shown).

Thus, the capacitor structure in the memory device is formed after the above steps.

In the resultant capacitor structure, each pair of the adjacent first electrode layer 22 and second electrode layer 24 constitute two capacitor plates of a sub-capacitor, and each of the first dielectric layers 21 and second dielectric layers 23, except for the top-most and bottom-most dielectric layer of the multi-layer structure, constitutes a dielectric layer of a sub-capacitor. In other words, the multi-layer structure comprises a stack of the first sub-capacitor comprising the first electrode layer 22, the second dielectric layer 23 and the second electrode layer 24 from the bottom to the top, and the second sub-capacitor comprising the second electrode layer 24, the first dielectric layer 21, and the first electrode layer 22 from the bottom to the top, arranged in an alternate manner. The first capacitor electrode 35 and the second capacitor electrode 36 connect all of the first sub-capacitors and the second sub-capacitors in parallel.

According to a preferred embodiment of the inventive method, the steps shown in FIGS. 15-16 are performed in this order for forming an MOSFET.

As shown in FIG. 15, the SOI wafer is turned upside down, and the bottom substrate 11 and the buried oxide layer 12 are removed from the SOI wafer by grinding so as to expose the SOI semiconductor layer 13 of the semiconductor structure of memory device.

Alternatively, if a bulk silicon substrate is used in the step shown in FIG. 1, the epitaxial semiconductor layer and the epitaxial SiGe layer are removed from the bulk silicon substrate. The grinding can be replaced by wet etching.

As shown in FIG. 16, an MOSFET can then be provided in the top semiconductor layer 13 with a conventional semiconductor process (for example, as disclosed in U.S. patent application No. US20090174031A1 of Wang Geng et al.). The MOSFET typically comprises a source region 39 and a drain region 40 formed in the SOI semiconductor layer 13, a gate dielectric 41 and a gate conductor 42 above a channel which is sandwiched between the source region 39 and the drain region 40, and sidewall spacers 43 disposed on either side of the gate conductor 42. Moreover, an interlayer dielectric (ILD) layer 45 is proved above the MOSFET. Metal wirings 47 are provided at the surface of the ILD layer 45, and vias 46 are provided in the ILD layer 45 for connecting the source region 39 with the metal wirings 47.

Typically, a side of the drain region 40 of the MOSFET contacts the polysilicon layer 16 directly, which provides an electrical connection between the MOSFET and the second capacitor electrode 36. Further, the source 39 of the MOSFET is connected to a bit line (not shown), and the gate conductor 42 is connected to a word line (not shown). The first capacitor electrode 35 is connected to ground.

While the invention has been described with reference to specific embodiments, to the description is illustrative of the invention. The description is not to be considered as limiting the invention. Various modifications and applications may occur for those skilled in the art without departing from the true spirit and scope of the invention as defined by the appended claims.

What is claimed is:

1. A memory device comprising an MOSFET formed in a semiconductor layer and a capacitor structure below the MOSFET, wherein the capacitor structure comprises two capacitor electrodes, and one of a source region and a drain region of the MOSFET is electrically connected to one of the two capacitor electrodes,
wherein the capacitor structure comprises a plurality of first sub-capacitors and a plurality of second sub-capacitors which are stacked in an alternate manner, each of the plurality of the first sub-capacitors and the plurality of the second sub-capacitors comprises a top capacitor plate, a bottom capacitor plate and a dielectric layer sandwiched therebetween, and the plurality of the first sub-capacitors and the plurality of the second sub-capacitors are connected in parallel with the two capacitor electrodes, and
wherein each of the first sub-capacitors has a bottom capacitor plate which is formed from a common first electrode layer with a top capacitor plate of an underlying second sub-capacitor, and each of the second sub-capacitors has a bottom capacitor plate with a top capacitor plate of an underlying first sub-capacitor, and wherein the first electrode layer and the second electrode layer are made of different conductive materials.

2. The memory device according to claim 1, wherein the different conductive materials have different etching rate.

3. The memory device according to claim 2, wherein each of the first electrode layer and the second conductive layer is the one selected from the group consisting of a metal layer, a doped polysilicon layer and any stack thereof.

4. The memory device according to claim 3, wherein the metal layer is made of one selected from a group consisting of TaC, TiN, TaTbN, TaErN, TaYbN, TaSiN, HfSiN, MoSiN, RuTax, NiTax, MoNx, TiSiN, TiCN, TaAlC, TiAlN, TaN, PtSix, Ni3Si, Pt, Ru, Ir, Mo, HfRu, and RuOx, or any of their combinations.

5. The memory device according to claim 4, wherein the first electrode layer is a polysilicon layer and the second electrode layer is a TiN layer.

6. The memory device according to claim 1, wherein the first sub-capacitors and the second sub-capacitors comprise the same dielectric material.

7. The memory device according to claim 1, wherein the first sub-capacitors and the second sub-capacitors comprise different dielectric materials.

8. The memory device according to claim 1, wherein
one of the two capacitor electrodes contacts all of the first electrode layer at a first side of the capacitor structure, while being electrically isolated from all of the second electrode layer at a second side of the capacitor structure; and
the other of the two capacitor electrodes contacts all of the second electrode layers at a second side of the capacitor structure, the second side being opposite to the first side, while being electrically isolated from all of the first electrode layer.

9. The memory device according to claim 1, further comprising an insulating layer which isolates the MOSFET and the capacitor structure, and a polysilicon layer which extends through the insulating layer and provides an electrical connection between one of the source region and the drain region of the MOSFET and one of the two capacitor electrodes.

10. A method for manufacturing a memory device, comprising steps of:
a) forming repeated stacks of a first dielectric layer, a first electrode layer, a second dielectric layer, and a second electrode layer in an alternate manner on a semiconductor substrate, so as to form a multi-layer structure, the semiconductor substrate having a bottom substrate, a sacrificial layer, and a top semiconductor layer;
b) etching a first side of the multi-layer structure, in which the exposed portion of the second electrode layer at the first side is selectively removed with respect to the first electrode layer, the first dielectric layer, and the second dielectric layer, so that recesses remain at the first side;
c) etching a second side of the multi-layer structure, in which the exposed portion of the first electrode layer at the second side is selectively removed with respect to the first dielectric layer, the second electrode layer, and the second dielectric layer, so that recesses remain at the second side;
d) forming a capping layer of insulating material on the multi-layer structure;
e) forming capacitor openings in the capping layer, which expose the first side and the second side of the multi-layer structure, and in which the insulating material remains in the recesses at the first side and the second side; and
f) forming two capacitor electrodes by filling the capacitor openings with a conductive material, the two capacitor electrodes contact directly all of the first electrode layer and all of the second electrode layer, respectively;
g) turning the semiconductor substrate upside down and removing the bottom substrate and the sacrificial layer;
h) forming a source region, a drain region, and a channel region therebetween of the MOSFET in the top semiconductor layer, wherein one of the source region and the drain region of the MOSFET is electrically connected to one of the two capacitor electrodes; and
i) forming a gate dielectric and a gate conductor above the channel region of the MOSFET.

11. The method according to claim 10, wherein the first electrode layer is a polysilicon layer, and the second electrode layer is a TiN layer.

12. The method according to claim 10, wherein the first dielectric layer and the second dielectric layer are made of the same dielectric material.

13. The method according to claim 10, wherein the first dielectric layer and the second dielectric layer are made of different dielectric materials.

14. The method according to claim 10, wherein the bottom substrate is a bulk silicon substrate.

15. The method according to claim 14, wherein the sacrificial layer is a SiGe layer.

16. The method according to claim 10, wherein the semiconductor substrate is an SOI substrate.

17. The method according to claim 10, wherein the step a) further comprises forming an insulating layer which isolates the top semiconductor layer of the semiconductor substrate and a multi-layer structure on the top semiconductor layer.

18. The method according to claim 17, wherein the step a) further comprises forming an opening in the insulating layer; filling the opening with a polysilicon layer, which polysilicon layer provides an electrical connection between one of the source region and the drain region of the MOSFET and one of the two capacitor electrodes.

19. The method according to claim 10, wherein the step e) further comprises forming sidewall spacers around the multi-layer structure in the capping layer; and forming the capacitor openings in the sidewall spacers, which expose the first side and the second side of the multi-layer structure, wherein the sidewall defines a rectangular region for each memory cell.
